(19) United States
(12) Patent Application Publication
(10) Pub. No.: US 2026/0293286 A1
(43) Pub. Date: Sep. 24, 2026

(54) SEMICONDUCTOR DEVICE

(71) Applicants: KABUSHIKI KAISHA TOSHIBA, Kawasaki-shi (JP); TOSHIBA ELECTRONIC DEVICES & STORAGE CORPORATION, Kawasaki-shi (JP)

(72) Inventors: Seiya SAKAKURA, Hakusan Ishikawa (JP); Tatsuya SHIRAISHI, Nonoichi Ishikawa (JP)

(73) Assignees: KABUSHIKI KAISHA TOSHIBA, Kawasaki-shi (JP); TOSHIBA ELECTRONIC DEVICES & STORAGE CORPORATION, Kawasaki-shi (JP)

(21) Appl. No.: 19/302,191

(22) Filed: Aug. 18, 2025

(30) Foreign Application Priority Data
Mar. 24, 2025 (JP) 2025-048599

(51) Int. Cl. H10D 84/00; H10D 84/01

(52) U.S. Cl. CPC H10D 84/146; H10D 84/0109

(57) ABSTRACT

A semiconductor device includes a first electrode, a semiconductor part located on the first electrode, a first dielectric film, a second dielectric film contacting the first dielectric film and including oxygen, a second electrode contacting the semiconductor part and the second dielectric film and including a metal, an insulating member, and a third electrode located inside the insulating member. A first trench and a second trench are formed in an upper surface of the semiconductor part and are separated from each other. The first dielectric film is located on at least a side surface of the first trench, contacts the semiconductor part and includes oxygen. An oxygen concentration of the second dielectric film is greater than an oxygen concentration of the first dielectric film. The second electrode is located inside the first trench and on the semiconductor part. The insulating member is located inside the second trench.

### CROSS-REFERENCE TO RELATED APPLICATIONS

This application is based upon and claims the benefit of priority from Japanese Patent Application No. 2025-048599, filed on Mar. 24, 2025; the entire contents of which are incorporated herein by reference.

### FIELD

Embodiments described herein relate generally to a semiconductor device.

### BACKGROUND

In recent years, semiconductor devices are being developed in which a field effect transistor part and a diode part formed of a Schottky junction are realized by embedding a metal member inside a source trench. In such a semiconductor device, it is desirable to increase the effective work function of a structure body located inside the source trench to set the threshold of the transistor part to a prescribed value.

### BRIEF DESCRIPTION OF THE DRAWINGS

FIG. 1 is a cross-sectional view showing a semiconductor device according to a first embodiment;

FIG. 2 is a cross-sectional view along line A-A′ shown in FIG. 1;

FIG. 3 is a partially enlarged cross-sectional view showing region C of FIG. 2;

FIGS. 4 to 10 are process cross-sectional views showing a method for manufacturing the semiconductor device according to the first embodiment;

FIG. 11 is a cross-sectional view showing a semiconductor device according to a second embodiment;

FIG. 12 is a cross-sectional view showing a semiconductor device according to a third embodiment; and

FIGS. 13 to 15 are process cross-sectional views showing a method for manufacturing the semiconductor device according to the third embodiment.

### DETAILED DESCRIPTION

In general, according to one embodiment, a semiconductor device includes a first electrode, a semiconductor part, a first dielectric film, a second dielectric film, a second electrode, an insulating member, and a third electrode. The semiconductor part is located on the first electrode. The semiconductor part is of a first conductivity type. A first trench and a second trench are formed in an upper surface of the semiconductor part. The first trench and the second trench are separated from each other. The first dielectric film is located on at least a side surface of the first trench. The first dielectric film contacts the semiconductor part and includes oxygen. The second dielectric film contacts the first dielectric film. The second dielectric film includes oxygen. An oxygen concentration of the second dielectric film is greater than an oxygen concentration of the first dielectric film. The second electrode is located inside the first trench and on the semiconductor part. The second electrode contacts the semiconductor part and the second dielectric film and includes a metal. The insulating member is located inside the second trench. The third electrode is located inside the insulating member.

### First Embodiment

A semiconductor device according to an embodiment is a semiconductor device for power control and is, for example, a MOSFET (Metal-Oxide-Semiconductor Field-Effect Transistor) with a built-in Schottky diode.

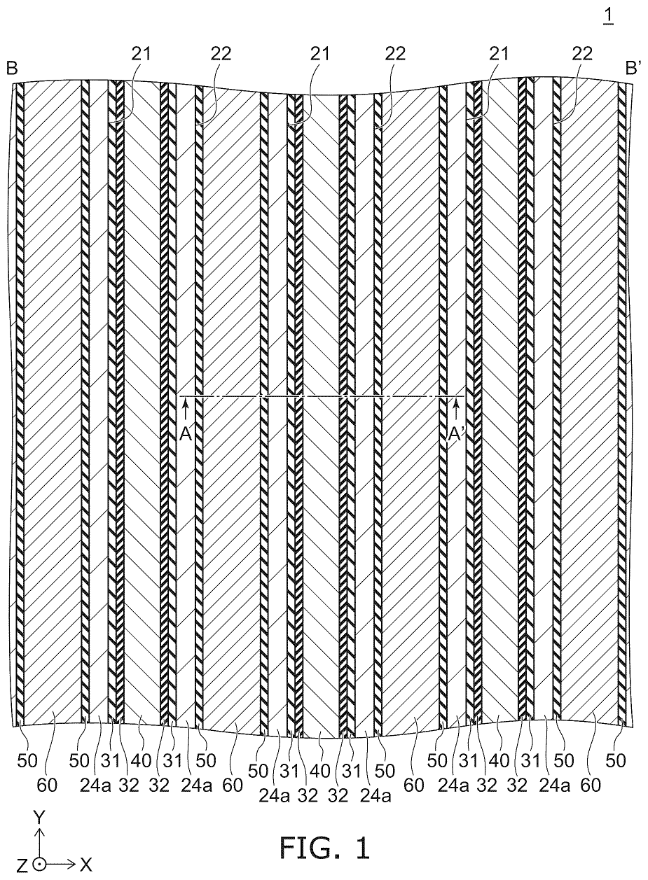

FIG. 1 is a cross-sectional view showing the semiconductor device according to the embodiment.

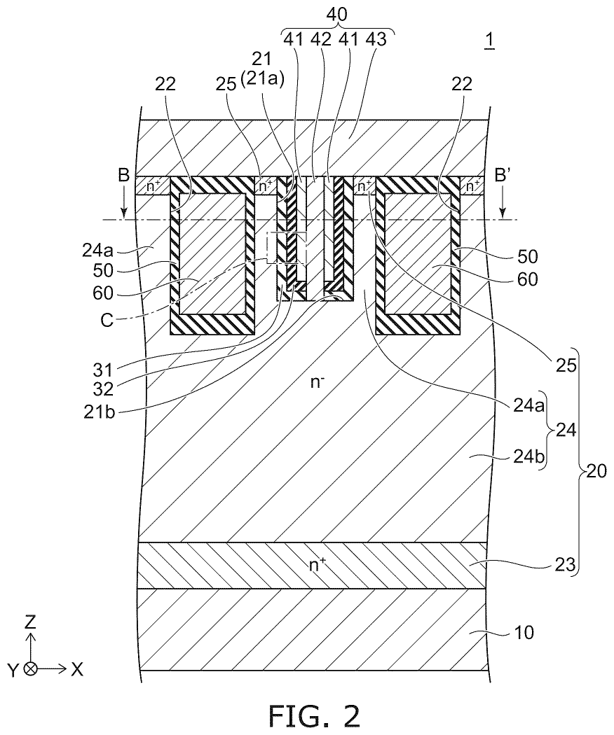

FIG. 2 is a cross-sectional view along line A-A′ shown in FIG. 1.

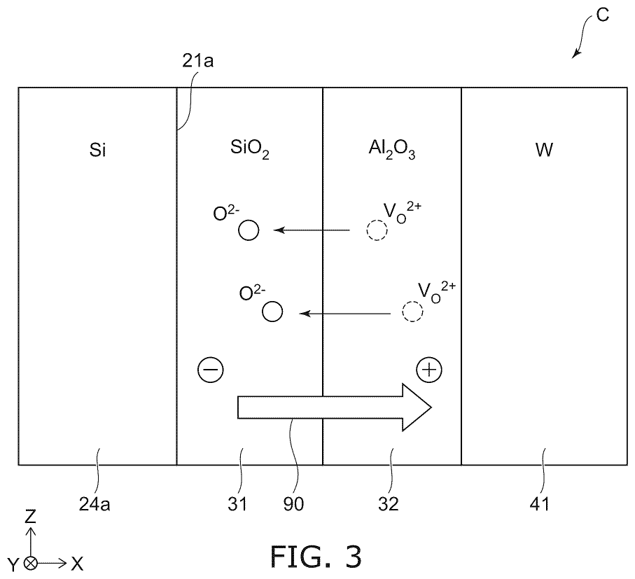

FIG. 3 is a partially enlarged cross-sectional view showing region C of FIG. 2.

FIG. 1 is a cross-sectional view along line B-B′ shown in FIG. 2.

As shown in FIGS. 1 to 3, the semiconductor device 1 according to the embodiment includes a drain electrode 10 (a first electrode), a silicon part 20 (a semiconductor part), a silicon oxide film 31 (a first dielectric film), an aluminum oxide film 32 (a second dielectric film), a source electrode 40 (a second electrode), an insulating member 50, and a gate electrode 60 (a third electrode).

An XYZ orthogonal coordinate system is employed for convenience of description in the specification hereinbelow. The direction from the drain electrode 10 toward the source electrode 40 is referred to as a “Z-direction”; the direction in which the gate electrode 60 extends is referred to as a “Y-direction”; and a direction orthogonal to the Z-direction and Y-direction is referred to as an “X-direction”. The Z-direction also is referred to as “up/above”, and the opposite direction also is referred to as “down/below”; however, these expressions are for convenience and are independent of the direction of gravity.

The drain electrode 10 is formed of, for example, titanium (Ti). However, the drain electrode 10 is not limited thereto. The drain electrode 10 may be a stacked body in which multiple metal layers are stacked.

The silicon part 20 is located on the drain electrode 10 and contacts the drain electrode 10. The silicon part 20 is made of single-crystal silicon (Si); and the conductivity type of the silicon part 20 is an n-type (a first conductivity type). A source trench 21 (a first trench) and a gate trench 22 (a second trench) that extend in the Y-direction are formed in the upper surface of the silicon part 20. The source trench 21 and the gate trench 22 are alternately arranged to be separated from each other in the X-direction. For example, the gate trench 22 is deeper than the source trench 21.

A drain layer 23, a drift layer 24, and a source layer 25 are stacked in this order in the silicon part 20. The conductivity type of the drain layer 23 is the n⁺-type; and the drain layer 23 contacts the drain electrode 10. As a result, the silicon part 20 is connected to the drain electrode 10. In the specification, “connected” refers to an electrical connection.

The drift layer 24 is located on the drain layer 23; and the conductivity type of the drift layer 24 is the n-type. In other words, the impurity concentration of the drift layer 24 is less than the impurity concentration of the drain layer 23. The source layer 25 is located on the drift layer 24; and the conductivity type of the source layer 25 is the n⁺-type. In other words, the impurity concentration of the source layer 25 is greater than the impurity concentration of the drift layer 24.

The source trench 21 extends through the source layer 25; and the lower end of the source trench 21 is positioned inside the drift layer 24. The gate trench 22 also extends through the source layer 25; and the lower end of the gate trench 22 is positioned inside the drift layer 24. Therefore, the source layer 25 and the upper part of the drift layer 24 are located between the source trench 21 and the gate trench 22. Hereinbelow, the part of the drift layer 24 positioned between the source trench 21 and the gate trench 22 is referred to as an “upper part 24a”; and the other part of the drift layer 24 is referred to as a “lower part 24b”. The source layer 25 and the upper part 24a of the drift layer 24 have band shapes extending in the Y-direction.

The insulating member 50 is located inside the gate trench 22. The insulating member 50 is made of an insulating material, and is made of, for example, silicon oxide (SiO₂). The insulating member 50 contacts the entire inner surface of the gate trench 22.

The gate electrode 60 is located inside the insulating member 50. The gate electrode 60 has a columnar shape extending in the Y-direction. The gate electrode 60 is made of p⁺-type polysilicon. The gate electrode 60 faces the upper part 24a of the drift layer 24 via a portion of the insulating member 50.

The silicon oxide film 31 is located on a side surface 21a of the source trench 21 and on two X-direction end parts of a bottom surface 21b of the source trench 21. The silicon oxide film 31 is not located on the X-direction central part of the bottom surface 21b. Therefore, inside one source trench 21, the silicon oxide film 31 is divided into two parts that are separated from each other in the X-direction. The silicon oxide film 31 contacts the silicon part 20. More specifically, the silicon oxide film 31 contacts the source layer 25 and the upper and lower parts 24a and 24b of the drift layer 24. The silicon oxide film 31 includes silicon oxide (SiO₂), and is made of, for example, silicon oxide. Accordingly, the silicon oxide film 31 includes oxygen (O).

The aluminum oxide film 32 contacts the silicon oxide film 31 and is separated from the silicon part 20 with the silicon oxide film 31 interposed. Inside one source trench 21, the aluminum oxide film 32 is divided into two parts that are separated from each other in the X-direction. The aluminum oxide film 32 includes aluminum oxide (Al₂O₃) and is made of, for example, aluminum oxide. Accordingly, the aluminum oxide film 32 includes oxygen.

Thus, the silicon oxide film 31 and the aluminum oxide film 32 are stacked on the side surface 21a of the source trench 21; the silicon oxide film 31 contacts the drift layer 24; and the aluminum oxide film 32 contacts the source electrode 40. The total thickness of the silicon oxide film 31 and the aluminum oxide film 32, i.e., the X-direction length on the side surface 21a, is, for example, less than 10 nm. The oxygen concentration (the 25 volume concentration) of the aluminum oxide film 32 is greater than the oxygen concentration (the volume concentration) of the silicon oxide film 31.

The source electrode 40 is located inside the source trench 21 and on the silicon part 20. The source electrode 40 includes a sidewall part 41 (a first metal part), a core part 42, and a flat plate part 43 (a second metal part).

Two sidewall parts 41 are arranged inside the source trench 21 to be separated from each other in the X-direction. The sidewall parts 41 contact the aluminum oxide films 32. For example, each sidewall part 41 has a band shape along the YZ-plane. The sidewall part 41 includes, for example, tungsten (W) and is made of, for example, tungsten.

The core part 42 is located between two sidewall parts 41 inside the source trench 21 and contacts the two sidewall parts 41. For example, the core part 42 has a band shape along the YZ-plane. The lower end of the core part 42 contacts the lower part 24b of the drift layer 24 at the X-direction central part of the bottom surface 21b of the source trench 21. The core part 42 includes, for example, tungsten and is made of, for example, tungsten. As a result, a Schottky barrier diode is formed in which the source electrode 40 is used as an anode, and the drift layer 24 is used as a cathode.

The flat plate part 43 is located on the silicon part 20, on the insulating member 50, on the silicon oxide film 31, on the aluminum oxide film 32, on the sidewall part 41, and on the core part 42; and the flat plate part 43 contacts these components. Therefore, the flat plate part 43 is connected to the source layer 25 of the silicon part 20, the sidewall part 41, and the core part 42. The flat plate part 43 includes, for example, titanium and is made of, for example, titanium.

The flat plate part 43 has an ohmic connection with the source layer 25 of the silicon part 20 at the upper surface of the silicon part 20. The source layer 25 is connected to the upper part 24a of the drift layer 24. As a result, a MOSFET (Metal-Oxide-Semiconductor Field-Effect Transistor) is formed of the source electrode 40, the gate electrode 60, the insulating member 50, the silicon part 20, and the drain electrode 10.

As described above, the sidewall part 41 and the core part 42 are made of, for example, tungsten; and the work function of tungsten is about 4.7 eV. The flat plate part 43 is made of, for example, titanium; and the work function of titanium is about 4.3 eV. Therefore, the work functions of the sidewall part 41 and the core part 42 are greater than the work function of the flat plate part 43. Although the material of the source electrode 40 is not limited to these examples, it is favorable for the work function of the source electrode 40 to be not less than 4 eV.

A method for manufacturing the semiconductor device 1 according to the embodiment will now be described.

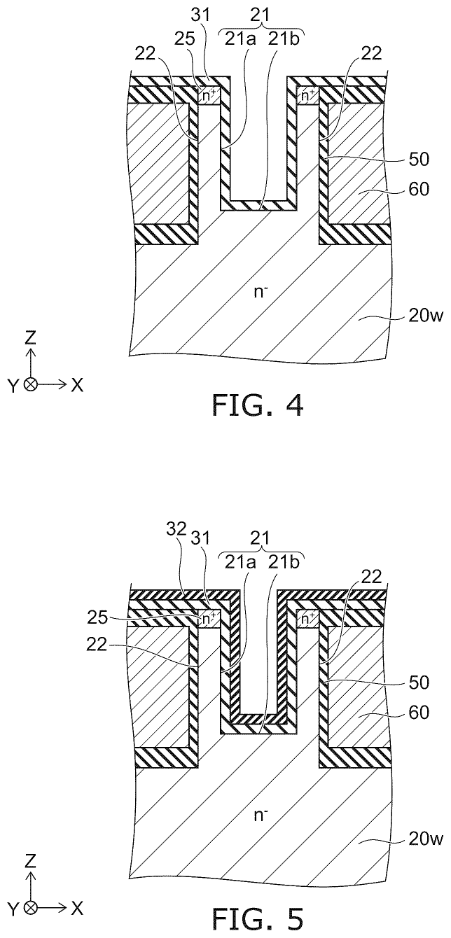

FIGS. 4 to 10 are process cross-sectional views showing the method for manufacturing the semiconductor device according to the embodiment.

FIGS. 4 to 10 show only a portion of the upper part of a silicon wafer 20w.

First, the silicon wafer 20w is prepared as shown in FIG. 4. The silicon wafer 20w is made of, for example, single-crystal silicon. The conductivity type of the lower part (not illustrated) of the silicon wafer 20w is the n⁺-type; and the conductivity type of the upper part of the silicon wafer 20w is the n⁻-type. Then, an impurity that forms donors is ion-implanted into the entire upper layer part of the silicon wafer 20w. As a result, the source layer 25 is formed in the upper layer part of the silicon wafer 20w.

Then, the multiple gate trenches 22 are formed in the upper surface of the silicon wafer 20w. The multiple gate trenches 22 are separated from each other in the X-direction; and each gate trench 22 extends in the Y-direction. Then, the insulating members 50 and the gate electrodes 60 are formed inside the gate trenches 22. Then, the source trench 21 that extends in the Y-direction is formed in the region of the upper surface of the silicon wafer 20w between the gate trenches 22.

Then, silicon oxide is deposited on the entire silicon wafer 20w by, for example, ALD (Atomic Layer Deposition). As a result, the silicon oxide film 31 is formed in a layer shape on the upper surface of the silicon wafer 20w, on the upper surface of the insulating member 50, and on the inner surface of the source trench 21. The thickness of the silicon oxide film 31 is, for example, 2 nm. At this time, the silicon oxide film 31 does not fill the entire interior of the source trench 21.

Continuing as shown in FIG. 5, aluminum oxide is deposited on the entire upper surface of the intermediate structure body shown in FIG. 4 by, for example, ALD. As a result, the aluminum oxide film 32 is formed in a layer shape on the silicon oxide film 31. The thickness of the aluminum oxide film 32 is, for example, 2 nm. At this time, the aluminum oxide film 32 does not fill the entire interior of the source trench 21.

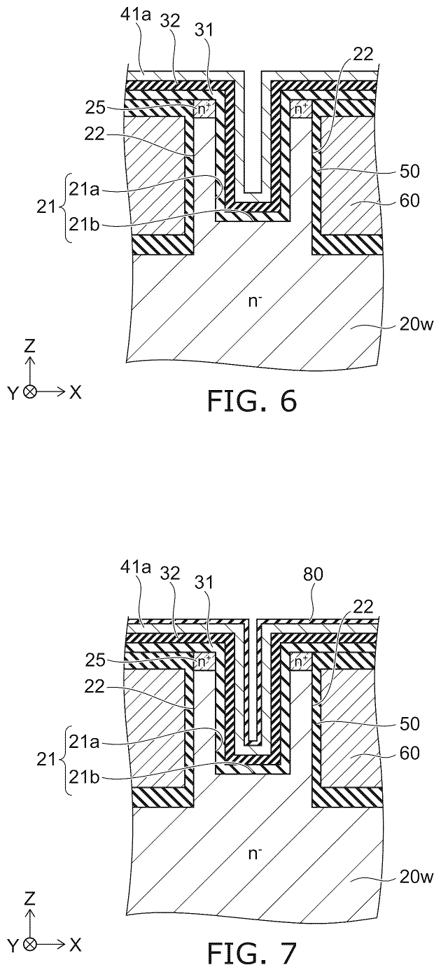

Then, as shown in FIG. 6, tungsten is deposited on the entire upper surface of the intermediate structure body shown in FIG. 5 by, for example, CVD (Chemical Vapor Deposition). As a result, a tungsten film 41a is formed in a layer shape on the aluminum oxide film 32. At this time, the tungsten film 41a does not fill the entire interior of the source trench 21.

Continuing as shown in FIG. 7, silicon nitride (Si₃N₄) is deposited on the entire upper surface of the intermediate structure body shown in FIG. 6. As a result, a mask film 80 is formed on the tungsten film 41a. The mask film 80 may be formed by depositing silicon oxide. As a result, the stacked film that is made of the silicon oxide film 31, the aluminum oxide film 32, the tungsten film 41a, and the mask film 80 covers the upper surface of the silicon wafer 20w, the upper surface of the insulating member 50, and the inner surface of the source trench 21. However, the interior of the source trench 21 is not completely filled with the stacked film; and a space remains.

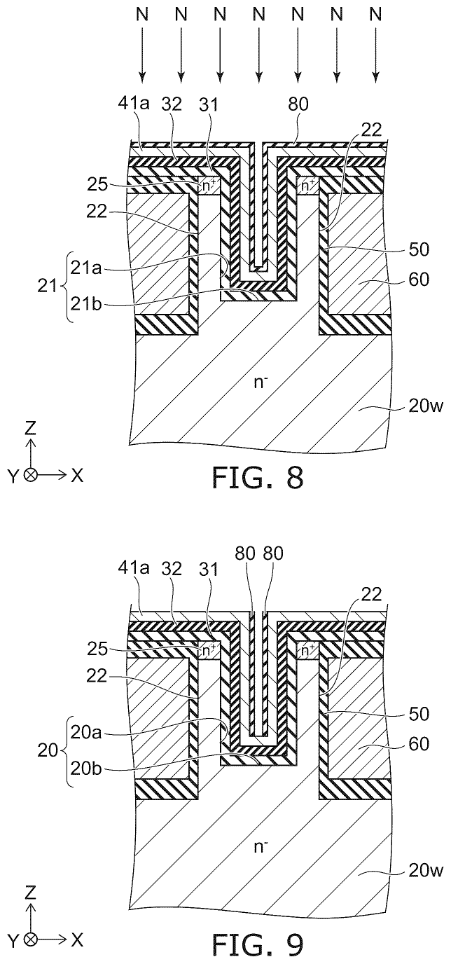

Then, as shown in FIG. 8, nitrogen (N) is ion-implanted from above into the entire upper surface of the intermediate structure body shown in FIG. 7. The dose is, for example, 3×10¹⁶ cm⁻². As a result, in the process shown in FIG. 9, the etching rate of the part of the mask film 80 into which nitrogen is implanted becomes high. Phosphorus (P) or boron (B) is ion-implanted when the mask film 80 is formed of silicon oxide and the mask film 80 is etched by hydrogen fluoride (HF). Phosphorus or carbon (C) is ion-implanted when the mask film 80 is formed of silicon oxide and the mask film 80 is dry-etched.

Continuing as shown in FIG. 9, the mask film 80 is etched. For example, dry etching such as RIE (Reactive Ion Etching) or the like of the mask film 80 is performed. At this time, the part of the mask film 80 facing the Z-direction has a relatively high etching rate because much nitrogen is implanted in the process shown in FIG. 8; and the part of the mask film 80 that does not face the Z-direction has a relatively low etching rate because little nitrogen is implanted. As a result, the part of the mask film 80 located on the side surface 21a of the source trench 21 remains; and the other part of the mask film 80 is removed.

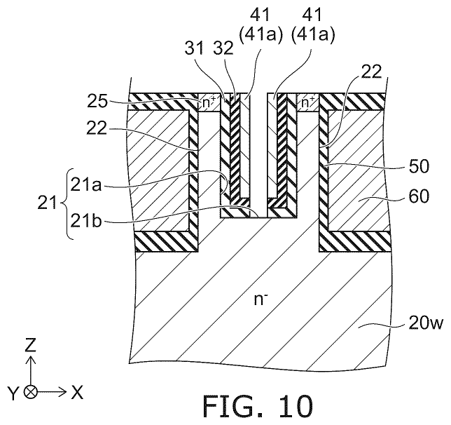

Then, as shown in FIG. 10, by etching tungsten, aluminum oxide, silicon oxide, and silicon nitride, the parts of the tungsten film 41a, the aluminum oxide film 32, and the silicon oxide film 31 located on the side surface 21a of the source trench 21 remain; and the other parts of the tungsten film 41a, the aluminum oxide film 32, and the silicon oxide film 31 are removed. As a result, the insulating member 50 and the source layer 25 of the silicon wafer 20w are exposed. The remaining part of the tungsten film 41a becomes the sidewall part 41. Then, the mask film 80 that remains on the side surface 21a of the source trench 21 is removed by, for example, wet etching. At this time, a step is formed in the tungsten film 41a after the mask film 80 is removed, but the step is not illustrated in FIG. 10.

Continuing, tungsten is deposited on the entire upper surface of the intermediate structure body shown in FIG. 10. Then, etch-back of the deposited tungsten is performed to expose the insulating member 50 and the source layer 25 of the silicon wafer 20w. As a result, the core part 42 is formed inside the source trench 21. The core part 42 is filled into the source trench 21. Then, as shown in FIG. 2, the flat plate part 43 is formed by depositing titanium. The source electrode 40 is formed of the sidewall part 41, the core part 42, and the flat plate part 43.

Then, the silicon wafer 20w is thinned by polishing from the lower surface of the silicon wafer 20w. Then, the drain electrode 10 is formed on the lower surface of the silicon wafer 20w. Then, the silicon wafer 20w is singulated into the multiple silicon parts 20 by dicing. At this time, the lowermost part of the silicon wafer 20w becomes the drain layer 23; the uppermost part of the silicon wafer 20w becomes the source layer 25; and the part between the drain layer 23 and the source layer 25 becomes the drift layer 24. Thus, the semiconductor device 1 is manufactured.

Operations of the semiconductor device 1 according to the embodiment will now be described.

First, basic operations of the semiconductor device 1 will be described.

As shown in FIG. 2, a higher potential than that of the source electrode 40 is applied to the drain electrode 10. In this state, for example, when the same potential as that of the source electrode 40 is applied to the gate electrode 60, a depletion layer spreads from the starting points of the interface between the silicon oxide film 31 and the drift layer 24 and the interface between the insulating member 50 and the drift layer 24; and the entire upper part 24a of the drift layer 24 is depleted. As a result, the semiconductor device 1 is set to an off state.

When a potential that is greater than a threshold Vth is applied to the gate electrode 60, an accumulation layer is formed at the part of the upper part 24a of the drift layer 24 contacting the insulating member 50; and a current starts to flow. As a result, a current flows through the path of the drain electrode 10, the drain layer 23 of the silicon part 20, the lower part 24b of the drift layer 24, the accumulation layer of the upper part 24a of the drift layer 24, the source layer 25, and the flat plate part 43 of the source electrode 40; and the semiconductor device 1 is switched to an on-state.

When the semiconductor device 1 is switched from the on-state to the off-state, the electrons that are present inside the drift layer 24 are discharged into the drain electrode 10 via the drain layer 23. When avalanche breakdown occurs, the electrons that are generated are discharged into the drain electrode 10 via the drain layer 23; and the holes that are generated are discharged from the bottom surface 21b of the source trench 21 into the flat plate part 43 of the source electrode 40 via the core part 42 of the source electrode 40.

When a potential that is higher than the drain electrode 10 is applied to the source electrode 40, a current flows through the path of the flat plate part 43 and the core part 42 of the source electrode 40, the lower part 24b of the drift layer 24, the drain layer 23, and the drain electrode 10 via the Schottky barrier diode formed at the bottom surface 21b of the source trench 21. As a result, for example, a free wheel current can flow.

Operations when the semiconductor device 1 is in the off-state will now be described in detail.

In the semiconductor device 1 as shown in FIG. 3, the sidewall part 41 of the source electrode 40 is formed of tungsten; and the upper part 24a of the drift layer 24 is formed of n-type silicon; therefore, a Schottky junction is formed between the sidewall part 41 and the upper part 24a of the drift layer 24.

The silicon oxide film 31 and the aluminum oxide film 32 are located between the sidewall part 41 and the upper part 24a of the drift layer 24. The oxygen concentration of the aluminum oxide film 32 is greater than the oxygen concentration of the silicon oxide film 31. Therefore, oxygen ions (O²⁻) included in the aluminum oxide film 32 diffuse into the silicon oxide film 31. As a result, oxygen vacancies (Vo²⁺) are generated inside the aluminum oxide film 32 and are positively charged, and excess oxygen ions (O²⁻) are generated inside the silicon oxide film 31 and are negatively charged. As a result, a dipole 90 from the silicon oxide film 31 toward the aluminum oxide film 32 is formed. As a result, the electrons inside the upper part 24a of the drift layer 24 move away from the silicon oxide film 31; and a depletion layer extends easily inside the upper part 24a. As a result, the threshold of the MOSFET can be adjusted to the desired value.

Effects of the embodiment will now be described.

According to the embodiment, the conductivity type of the upper part 24a of the drift layer 24 is the n⁻-type; and the source electrode 40 and the gate electrode 60 generate a depletion layer in the upper part 24a; therefore, the MOSFET of the semiconductor device 1 is normally-off. The conduction of the MOSFET is controlled by controlling the potential of the gate electrode 60. As a result, the reverse recovery charge can be reduced because there is no p-n junction in the silicon part 20, and no hole injection occurs during the reverse recovery operation.

According to the embodiment, the dipole 90 is formed by providing the silicon oxide film 31 and the aluminum oxide film 32 between the upper part 24a of the drift layer 24 and the sidewall part 41 of the source electrode 40. As a result, the effective work function of the source electrode 40 is high, and the barrier height between the source electrode 40 and the drift layer 24 can be increased. By increasing the barrier height, the effect of depleting the drift layer 24 can be increased, and the threshold of the MOSFET can be increased.

Thus, according to the embodiment, by forming the dipole 90, it is unnecessary to use a metal having a markedly high work function such as, for example, platinum (Pt) or the like as the material of the sidewall part 41 of the source electrode 40; and material alternatives are increased. As a result, for example, the sidewall part 41 can be formed of a metal having high patternability such as tungsten. As a result, the productivity of the semiconductor device 1 is increased.

According to the embodiment, a Schottky barrier diode is formed by contact between the core part 42 of the source electrode 40 and the lower part 24b of the drift layer 24. As a result, when a higher potential than that of the drain electrode 10 is applied to the source electrode 40, a free wheel current can flow with a low resistance.

Although an example is illustrated in the embodiment in which the dipole 90 is formed by the silicon oxide film 31 and the aluminum oxide film 32, the combination of dielectric films including oxygen is not limited thereto. It is sufficient to provide the first dielectric film in contact with the silicon part 20, to provide the second dielectric film in contact with the first dielectric film and the source electrode 40, and to set the oxygen concentration of the second dielectric film to be greater than the oxygen concentration of the first dielectric film.

Although an example is illustrated in the embodiment in which the sidewall part 41 of the source electrode 40 is formed of tungsten, the material of the sidewall part 41 is not limited to tungsten. It is sufficient for the material of the sidewall part 41 to be a material that provides the necessary work function in combination with the dipole.

### Second Embodiment

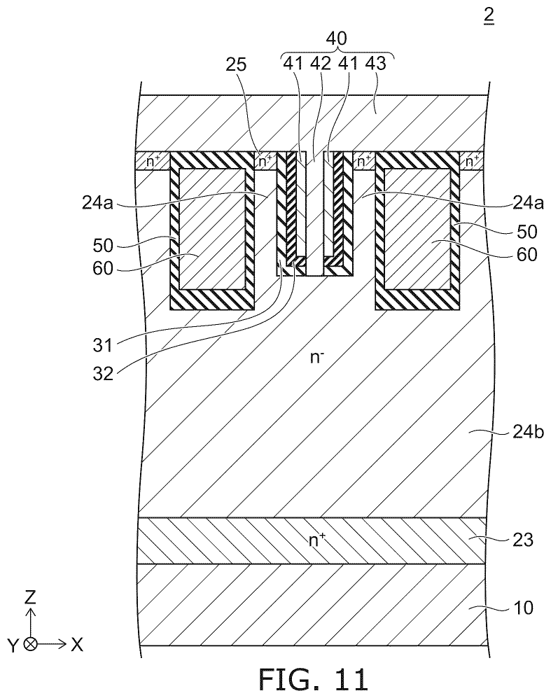

FIG. 11 is a cross-sectional view showing a semiconductor device according to an embodiment.

As shown in FIG. 11, the semiconductor device 2 according to the embodiment differs from the semiconductor device 1 according to the first embodiment in that the core part 42 of the source electrode 40 is formed as one monolithic piece with the flat plate part 43. The core part 42 and the flat plate part 43 are formed of titanium or tungsten.

According to the embodiment, the core part 42 and the flat plate part 43 can be manufactured in one process. Therefore, the productivity of the semiconductor device 2 according to the embodiment is high. Otherwise, the configuration, manufacturing method, operations, and effects according to the embodiment are similar to those of the first embodiment.

### Third Embodiment

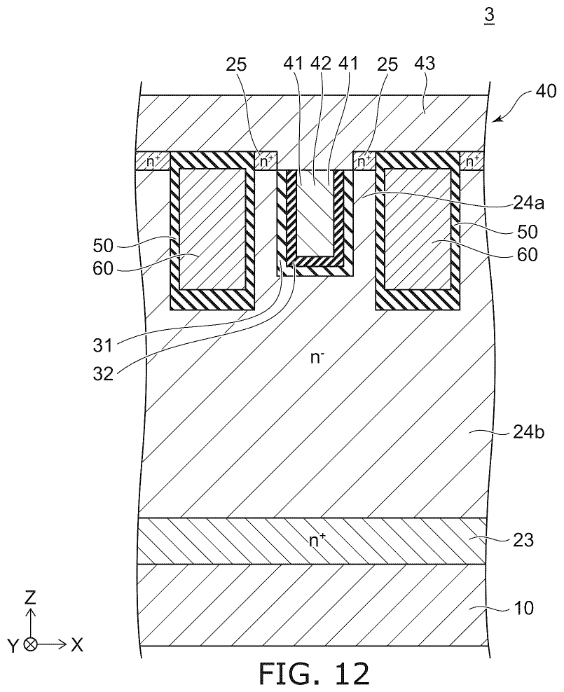

FIG. 12 is a cross-sectional view showing a semiconductor device according to an embodiment.

As shown in FIG. 12, the semiconductor device 3 according to the embodiment differs from the semiconductor device 1 according to the first embodiment in that the sidewall part 41 and the core part 42 of the source electrode 40 are formed as one monolithic piece; and the silicon oxide film 31 and the aluminum oxide film 32 are located on the entire bottom surface 21b of the source trench 21.

According to the embodiment, the sidewall part 41 and the core part 42 of the source electrode 40 are formed of, for example, tungsten; and the flat plate part 43 is formed of, for example, titanium. The silicon oxide film 31 contacts the lower part 24b of the drift layer 24 at the bottom surface 21b of the source trench 21; and the source electrode 40 is separated from the lower part 24b of the drift layer 24 with the aluminum oxide film 32 and the silicon oxide film 31 interposed.

A method for manufacturing the semiconductor device according to the embodiment will now be described.

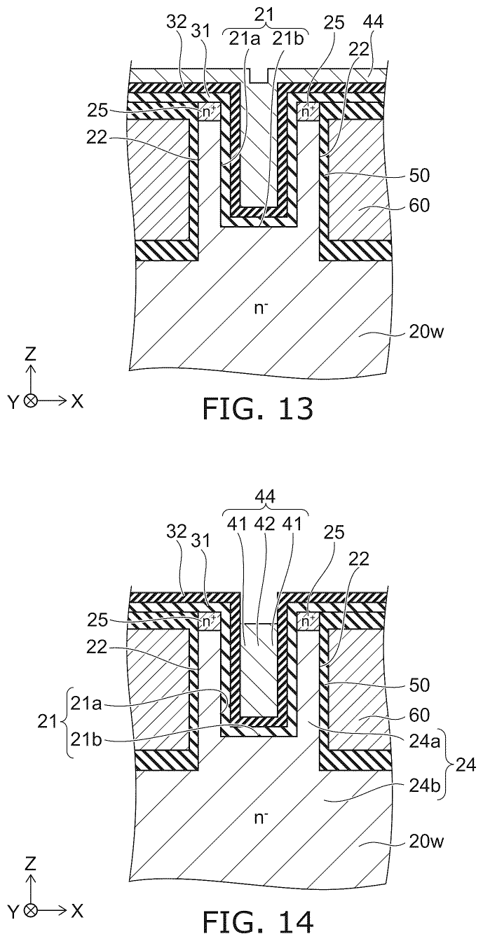

FIGS. 13 to 15 are process cross-sectional views showing the method for manufacturing the semiconductor device according to the embodiment.

Only a portion of the upper part of the silicon wafer 20w is shown in FIGS. 13 to 15.

First, the processes shown in FIGS. 4 and 5 are performed.

Then, as shown in FIG. 13, a tungsten film 44 is formed by depositing tungsten on the entire surface by, for example, CVD. At this time, the tungsten film 44 fills the entire interior of the source trench 21.

Continuing as shown in FIG. 14, etch-back of the tungsten film 44 is performed. As a result, the part of the tungsten film 44 deposited on the silicon wafer 20w, the part of the tungsten film 44 deposited on the insulating member 50, and the part of the tungsten film 44 deposited in the upper part of the source trench 21 are removed, and the tungsten film 44 remains in only the lower part of the source trench 21. At this time, the upper surface of the tungsten film 44 remaining inside the source trench 21 is positioned higher than the interface between the drift layer 24 and the source layer 25. The sidewall part 41 and the core part 42 are formed of the tungsten film 44 to be one monolithic piece in the lower part of the source trench 21.

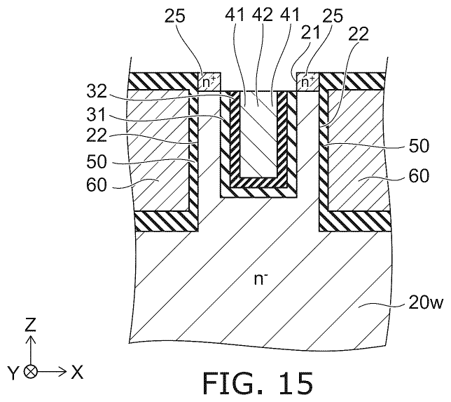

Then, etch-back of the aluminum oxide film 32 and the silicon oxide film 31 is performed as shown in FIG. 15. As a result, the parts of the aluminum oxide film 32 and the silicon oxide film 31 deposited on the silicon wafer 20w, the parts of the aluminum oxide film 32 and the silicon oxide film 31 deposited on the insulating member 50, and the parts of the aluminum oxide film 32 and the silicon oxide film 31 deposited in the upper part of the source trench 21 are removed; and only the parts of the aluminum oxide film 32 and the silicon oxide film 31 deposited in the lower part of the source trench 21, i.e., the parts located between the silicon wafer 20w and the sidewall part 41, remain.

Continuing as shown in FIG. 12, the flat plate part 43 is formed by depositing titanium. The source electrode 40 is formed of the sidewall part 41, the core part 42, and the flat plate part 43. The subsequent processes are similar to those of the first embodiment. Specifically, the silicon wafer 20w is thinned by polishing the lower surface of the silicon wafer 20w; the drain electrode 10 is formed on the lower surface of the silicon wafer 20w; and the silicon wafer 20w is singulated. Thus, the semiconductor device 3 is manufactured.

According to the embodiment, the manufacturing processes can be simplified compared to the first embodiment. Otherwise, the configuration, manufacturing method, operations, and effects according to the embodiment are similar to those of the first embodiment.

According to the embodiments above, a semiconductor device and a method for manufacturing a semiconductor device can be realized in which the effective work function of the structure body located inside the source trench can be high.

While certain embodiments have been described, these embodiments have been presented by way of example only, and are not intended to limit the scope of the inventions. Indeed, the novel embodiments described herein may be embodied in a variety of other forms; furthermore, various omissions, substitutions and changes in the form of the embodiments described herein may be made without departing from the spirit of the inventions. The accompanying claims and their equivalents are intended to cover such forms or modifications as would fall within the scope and spirit of the inventions.

Embodiments include the following aspects.

### Note 1

A semiconductor device, comprising:
a first electrode;
a semiconductor part located on the first electrode, the semiconductor part being of a first conductivity type, a first trench and a second trench being formed in an upper surface of the semiconductor part, the first trench and the second trench being separated from each other;
a first dielectric film located on at least a side surface of the first trench, the first dielectric film contacting the semiconductor part and including oxygen;
a second dielectric film contacting the first dielectric film, the second dielectric film including oxygen, an oxygen concentration of the second dielectric film being greater than an oxygen concentration of the first dielectric film;
a second electrode located inside the first trench and on the semiconductor part, the second electrode contacting the semiconductor part and the second dielectric film and including a metal;
an insulating member located inside the second trench; and
a third electrode located inside the insulating member.

### Note 2

The device according to note 1, wherein
the first dielectric film includes silicon oxide.

### Note 3

The device according to note 1 or 2, wherein
the second dielectric film includes aluminum oxide.

### Note 4

The device according to any one of notes 1-3, wherein
the second electrode contacts the semiconductor part at a bottom surface of the first trench.

### Note 5

The device according to any one of notes 1-3, wherein
the first dielectric film and the second dielectric film also are located on a bottom surface of the first trench, and
the first dielectric film contacts the semiconductor part at the bottom surface of the first trench.

### Note 6

The device according to any one of notes 1-5, wherein
a total thickness of the first and second dielectric films is less than 10 nm.

### Note 7

The device according to any one of notes 1-6, wherein
the semiconductor part and the second electrode form a Schottky junction.

### Note 8

The device according to any one of notes 1-7, wherein
the second electrode includes:
   a first metal part contacting the second dielectric film; and
   a second metal part contacting the semiconductor part, and
a work function of the first metal part is greater than a work function of the second metal part.

### Note 9

The device according to note 8, wherein
the first metal part includes tungsten.

### Note 10

The device according to any one of notes 1-9, wherein
the second electrode includes tungsten.

### Note 11

The device according to any one of notes 1-10, wherein
a work function of the second electrode is not less than 4 eV.

What is claimed is:

1. A semiconductor device, comprising:
a first electrode;
a semiconductor part located on the first electrode, the semiconductor part being of a first conductivity type, a first trench and a second trench being formed in an upper surface of the semiconductor part, the first trench and the second trench being separated from each other;
a first dielectric film located on at least a side surface of the first trench, the first dielectric film contacting the semiconductor part and including oxygen;
a second dielectric film contacting the first dielectric film, the second dielectric film including oxygen, an oxygen concentration of the second dielectric film being greater than an oxygen concentration of the first dielectric film;
a second electrode located inside the first trench and on the semiconductor part, the second electrode contacting the semiconductor part and the second dielectric film and including a metal;
an insulating member located inside the second trench; and
a third electrode located inside the insulating member.

2. The device according to claim 1, wherein
the first dielectric film includes silicon oxide.

3. The device according to claim 1, wherein
the second dielectric film includes aluminum oxide.

4. The device according to claim 1, wherein
the second electrode contacts the semiconductor part at a bottom surface of the first trench.

5. The device according to claim 1, wherein
the first dielectric film and the second dielectric film also are located on a bottom surface of the first trench, and
the first dielectric film contacts the semiconductor part at the bottom surface of the first trench.

6. The device according to claim 1, wherein
a total thickness of the first and second dielectric films is less than 10 nm.

7. The device according to claim 1, wherein
the semiconductor part and the second electrode form a Schottky junction.

8. The device according to claim 1, wherein
the second electrode includes:
a first metal part contacting the second dielectric film; and
a second metal part contacting the semiconductor part, and
a work function of the first metal part is greater than a work function of the second metal part.

9. The device according to claim 8, wherein
the first metal part includes tungsten.

10. The device according to claim 1, wherein
the second electrode includes tungsten.

11. The device according to claim 1, wherein
a work function of the second electrode is not less than 4 eV.
